(19) United States
(12) Patent Application Publication
(10) Pub. No.: US 2020/0406307 A1
(43) Pub. Date: Dec. 31, 2020

(54) TWELVE-INCH AND EIGHT-INCH COMPATIBLE FURNACE TUBE WASHING TANK MECHANISM AND FURNACE TUBE WASHING TANK DEVICE

(71) Applicant: Shanghai STN electromechanical equipment Co.,Ltd, Shanghai (CN)

(72) Inventors: LIQIANG WANG, SHANGHAI (CN); LINHAI GE, SHANGHAI (CN); SHUANGSHENG DING, SHANGHAI (CN); JIE LI, SHANGHAI (CN); JIANLONG ZHAO, SHANGHAI (CN)

(73) Assignee: Shanghai STN electromechanical equipment Co.,Ltd

(21) Appl. No.: 16/882,768

(22) Filed: May 26, 2020

Related U.S. Application Data
(63) Continuation of application No. PCT/CN2019/096230, filed on Jul. 16, 2019.

(30) Foreign Application Priority Data
Jun. 28, 2019 (CN) 201910571602.5

(51) Int. Cl. B08B 3/04

(52) U.S. Cl. CPC B08B 3/044; H01L 21/6704

(57) ABSTRACT

The invention relates to a twelve-inch and eight-inch compatible furnace tube washing tank mechanism and a furnace tube washing tank device. A driving wheel is arranged at the upper part of a support frame; a first gear on the driving wheel is engaged with a second gear of a driven wheel; two sides of a third gear of the driven wheel are respectively engaged with a fourth gear of a first transmission shaft. The twelve-inch and eight-inch compatible furnace tube washing tank mechanism is compatible with a variety of specifications and is capable of improving the efficiency and reducing the cost.

### CROSS-REFERENCE TO RELATED APPLICATIONS

This application is a continuation of International Patent Application No. PCT/CN2019/096230 with an international filing date of Jul. 16, 2019, designating the United States, now pending, and further claims priority benefits to CHINESE Patent Applications No. 201910571602.5, filed on Jun. 28, 2019. The contents of all of the aforementioned applications, including any intervening amendments thereto, are incorporated herein by reference.

### TECHNICAL FIELD

The invention relates to the technical field of semiconductor devices, in particular to a twelve-inch and eight-inch compatible furnace tube washing tank mechanism and a furnace tube washing tank device.

### BACKGROUND

The original material of the wafer is silicon; inexhaustible silicon oxide exists on the surface of the earth's crust; silicon oxide ores are refined by an electric arc furnace, chlorinated with hydrochloric acid and then distilled to produce high-purity polycrystalline silicon; the purity of the polycrystalline silicon reaches up to 99.999999999%; the polycrystalline silicon is melted in a wafer manufacturing plant, a seed crystal is planted in a molten solution, then the seed crystal is slowly pulled out to form a cylindrical monocrystalline silicon crystal bar; the silicon crystal bar is gradually generated by a seed crystal with a determined crystal surface orientation in a molten-state silicon raw material, so that the process is called as “crystal growth”. The silicon crystal bar becomes a basic raw material which is a silicon wafer called as “wafer” of an integrated circuit factory after cutting, barreling, slicing, chamfering, polishing, laser engraving and packaging.

The conventional semiconductor wafer wet washing machine is a single-row tank type washing machine, namely one or more tanks are arranged between a Loader and an Unloader; each tank is used for washing or rinsing by using an acid solution, an alkaline solution and pure water as required according to the design specification or requirement; the wafers are generally dried by a drying tank before unloading the wafers; and a general washing machine is equipped with a carrying mechanism for automatically carrying the wafers or wafer boxes loaded with the wafers among different tanks.

In the prior art, the furnace tube washing tank device is not compatible with different specifications of wafers; and one set of device is only capable of washing one specification of wafers and is not conducive to improvement of the efficiency and reduction of the cost, so that a twelve-inch and eight-inch compatible furnace tube washing tank mechanism which is compatible with a variety of specifications and is capable of improving the efficiency and reducing the cost is needed.

### SUMMARY OF THE INVENTION

The invention aims to provide a twelve-inch and eight-inch compatible furnace tube washing tank mechanism and a furnace tube washing device so as to achieve the effects of being compatible with a variety of specifications, improving the efficiency and reducing the cost.

According to a first aspect of the invention, the invention provides a twelve-inch and eight-inch compatible furnace tube washing tank mechanism, characterized in that the twelve-inch and eight-inch compatible furnace tube washing tank mechanism comprises:

a support frame; a driving wheel is arranged at the upper part of the support frame; a first gear on the driving wheel is engaged with a second gear of a driven wheel; two sides of a third gear of the driven wheel are respectively engaged with a fourth gear of a first transmission shaft; the driven wheel drives an eight-inch furnace tube;

a fifth gear of the first transmission shaft is engaged with a sixth gear of a second transmission shaft; transmission wheels are respectively arranged on the sides of the fifth gear and the sixth gear; a seventh gear of the first transmission shaft is engaged with an eighth gear of a third transmission shaft; a ninth gear of the third transmission shaft is engaged with a tenth gear of a fourth transmission shaft; an eleventh gear of the fourth transmission shaft is engaged with a twelfth gear of a fifth transmission shaft; the transmission wheels drive a twelve-inch furnace tube; transmission wheels are respectively arranged on the sides of the tenth gear, the eleventh gear and the twelfth gear;

the driving wheel, the first transmission shaft, the second transmission shaft, the third transmission shaft, the fourth transmission shaft and the fifth transmission shaft are respectively fixed on the support frame through bearings.

The second gear and the third gear of the driven wheel are concentrically arranged.

The outer diameter of the second gear of the driven wheel is larger than that of the third gear.

The transmission wheels are circular wheels.

The support frame is L-shaped.

More than one hook are arranged on the side of the twelve-inch furnace tube; the lower parts of the hooks are hook bodies which wrap the twelve-inch furnace tube, and the upper parts of the hooks are mounting blocks.

The driving wheel, the first transmission shaft, the second transmission shaft, the third transmission shaft, the fourth transmission shaft and the fifth transmission shaft are parallel to each other.

The second transmission shaft is located at radial middle parts of the upper parts of the first transmission shaft and the third transmission shaft; and the first transmission shaft, the second transmission shaft and the third transmission shaft are fixed by two support blocks.

The fifth transmission shaft is located at radial middle parts of the upper parts of the third transmission shaft and the fourth transmission shaft; and the third transmission shaft, the fourth transmission shaft and the fifth transmission shaft are fixed by two support blocks.

According to a second aspect of the invention, the invention provides a furnace tube washing tank device comprising the above-described twelve-inch and eight-inch compatible furnace tube washing tank mechanism.

A driving wheel is arranged at the upper part of a support frame; a first gear on the driving wheel is engaged with a second gear of a driven wheel; two sides of a third gear of the driven wheel are respectively engaged with a fourth gear of a first transmission shaft; the driven wheel drives an eight-inch furnace tube; a fifth gear of the first transmission shaft is engaged with a sixth gear of a second transmission shaft; transmission wheels are respectively arranged on the sides of the fifth gear and the sixth gear; a seventh gear of the first transmission shaft is engaged with an eighth gear of a third transmission shaft; a ninth gear of the third transmission shaft is engaged with a tenth gear of a fourth transmission shaft; an eleventh gear of the fourth transmission shaft is engaged with a twelfth gear of a fifth transmission shaft; the transmission wheels drive a twelve-inch furnace tube; the transmission wheels are respectively arranged on the sides of the tenth gear, the eleventh gear and the twelfth gear; and the driving wheel, the first transmission shaft, the second transmission shaft, the third transmission shaft, the fourth transmission shaft and the fifth transmission shaft are respectively fixed on the support frame through bearings.

The twelve-inch and eight-inch compatible furnace tube washing tank mechanism is compatible with a variety of specifications and is capable of improving the efficiency and reducing the cost.

### BRIEF DESCRIPTION OF THE DRAWINGS

In order to explain the technical solutions of the embodiments of the invention or the prior art more clearly, the drawings needed to be used in the description of the embodiments or the prior art are briefly introduced below. Obviously, the drawings in the following description are only some embodiments of the invention. Those of ordinary skill in the art can also obtain other drawings according to the drawings under the precondition that no creative labor is offered.

FIG. 1 is a structural schematic diagram of the twelve-inch and eight-inch compatible furnace tube washing tank mechanism in one embodiment of the invention.

FIG. 2 is a front-view schematic diagram of the twelve-inch and eight-inch compatible furnace tube washing tank mechanism in one embodiment of the invention.

FIG. 3 is a side-view schematic diagram of the twelve-inch and eight-inch compatible furnace tube washing tank mechanism in one embodiment of the invention.

In the drawings, 1 represents the support frame, 2 represents the driving wheel, 3 represents the eight-inch furnace tube, 4 represents the twelve-inch furnace tube, 5 represents the driven wheel, 6 represents the first transmission shaft, 7 represents the second transmission shaft, 8 represents the third transmission shaft, 9 represents the fourth transmission shaft, 10 represents the fifth transmission shaft, 11 represents the transmission wheel, 12 represents the hook, 13 represents the first gear, 14 represents the second gear, 15 represents the third gear, 16 represents the fourth gear, 17 represents the fifth gear, 18 represents the sixth gear, 19 represents the seventh gear, 20 represents the eighth gear, 21 represents the ninth gear, 22 represents the tenth gear, 23 represents the eleventh gear, and 24 represents the twelfth gear.

### DETAILED DESCRIPTION OF THE EMBODIMENTS

The technical solutions of the embodiments of the invention will be clearly and completely described below in combination of the drawings in the embodiments of the invention. Obviously, the described embodiments are only part of the embodiments of the invention, but not all of the embodiments. Based on the embodiments of the invention, all other embodiments obtained by those of ordinary skill in the art under the precondition that no creative labor is offered shall fall within the protection scope of the invention.

The terms such as “first”, “second”, “third” and “fourth” (if exist) in the specification, the claims and the above drawings of the invention are used for distinguishing similar objects and are not necessarily used for describing particular orders or sequences. It should be understood that the data used in this way is interchangeable at an appropriate situation, so that the embodiments of the invention described herein can be implemented in sequences other than the sequences which are illustrated or described herein. In addition, the terms “comprise” and “have” as well as any variants thereof are intended to cover non-exclusive inclusions; for example, processes, methods, systems, products, or devices which comprise a series of steps or units are not necessarily limited to the steps or units which are clearly listed, but may comprise other steps or units which are not clearly listed or are inherent to the processes, the methods, the products or the devices.

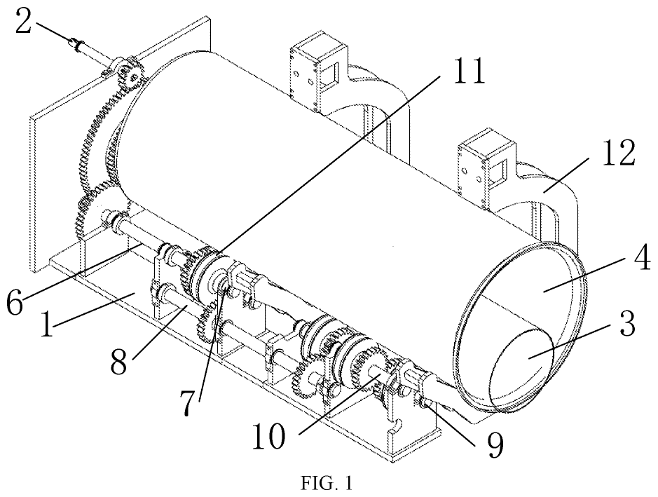

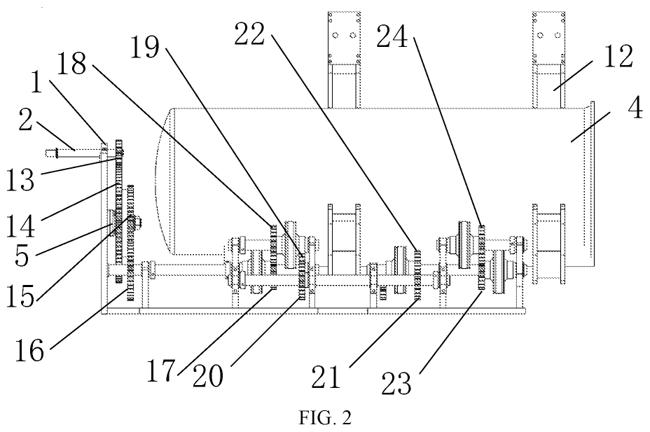

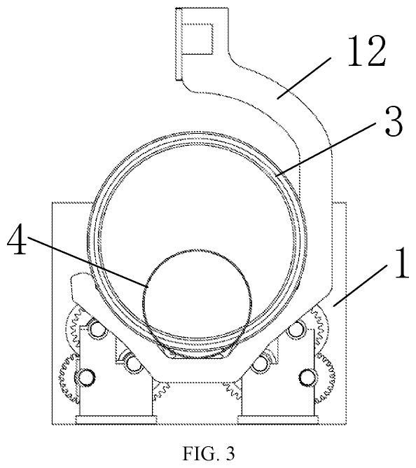

FIG. 1 is a structural schematic diagram of the twelve-inch and eight-inch compatible furnace tube washing tank mechanism in one embodiment of the invention; FIG. 2 is a front-view schematic diagram of the twelve-inch and eight-inch compatible furnace tube washing tank mechanism in one embodiment of the invention; FIG. 3 is a side-view schematic diagram of the twelve-inch and eight-inch compatible furnace tube washing tank mechanism in one embodiment of the invention.

With reference to FIGS. 1-3, the invention provides a twelve-inch and eight-inch compatible furnace tube washing tank mechanism, comprising a support frame 1, wherein a driving wheel 2 is arranged at the upper part of the support frame 1; a first gear 13 on the driving wheel 2 is engaged with a second gear 14 of a driven wheel 5; two sides of a third gear 15 of the driven wheel 5 are respectively engaged with a fourth gear 16 of a first transmission shaft 6; the driven wheel 5 drives an eight-inch furnace tube 3; a fifth gear 17 of the first transmission shaft 6 is engaged with a sixth gear 18 of a second transmission shaft 7; transmission wheels 11 are respectively arranged on the sides of the fifth gear 17 and the sixth gear 18; a seventh gear 19 of the first transmission shaft 6 is engaged with an eighth gear 20 of a third transmission shaft 8; a ninth gear 21 of the third transmission shaft 8 is engaged with a tenth gear 22 of a fourth transmission shaft 9; an eleventh gear 23 of the fourth transmission shaft 9 is engaged with a twelfth gear 24 of a fifth transmission shaft 10; the transmission wheels 11 drive a twelve-inch furnace tube 4; the transmission wheels 11 are respectively arranged on the sides of the tenth gear 22, the eleventh gear 23 and the twelfth gear 24; the driving wheel 2, the first transmission shaft 6, the second transmission shaft 7, the third transmission shaft 8, the fourth transmission shaft 9 and the fifth transmission shaft 10 are respectively fixed on the support frame 1 through bearings.

The second gear and the third gear of the driven wheel 5 are concentrically arranged; the outer diameter of the second gear of the driven wheel 5 is larger than that of the third gear; the transmission wheels 11 are circular wheels; the support frame 1 is L-shaped; more than one hook 12 are arranged on the side of the twelve-inch furnace tube 4; the lower parts of the hooks 12 are hook bodies which wrap the twelve-inch furnace tube 4, and the upper parts of the hooks are mounting blocks; the driving wheel 2, the first transmission shaft 6, the second transmission shaft 7, the third transmission shaft 8, the fourth transmission shaft 9 and the fifth transmission shaft 10 are parallel to each other; the second transmission shaft 7 is located at radial middle parts of the upper parts of the first transmission shaft 6 and the third transmission shaft 8; the first transmission shaft 6, the second transmission shaft 7 and the third transmission shaft 8 are fixed by two support blocks; the fifth transmission shaft 10 is located at radial middle parts of the upper parts of the third transmission shaft 8 and the fourth transmission shaft 9; and the third transmission shaft 8, the fourth transmission shaft 9 and the fifth transmission shaft 10 are fixed by two support blocks.

The driving wheel 2 is arranged at the upper part of the support frame 1; the first gear 13 is driven to rotate by the driving wheel 2 under driving of a motor so as to drive the second gear 14 of the driven wheel 5; the driven wheel 5 drives the eight-inch furnace tube 3; the driven wheel 5 rotates; two sides of the third gear 15 are respectively engaged with the fourth gear 16 of the first transmission shaft 6 so as to transfer kinetic energy down; the fifth gear 17 of the first transmission shaft 6 is engaged with the sixth gear 18 of the second transmission shaft 7, the seventh gear 19 of the first transmission shaft 6 is engaged with the eighth gear 20 of the third transmission shaft 8, the ninth gear 21 of the third transmission shaft 8 is engaged with the tenth gear 22 of the fourth transmission shaft 9, and the eleventh gear 23 of the fourth transmission shaft 9 is engaged with the twelfth gear 24 of the fifth transmission shaft 10, so that the kinetic energy is transferred in sequence; and the driving wheel 2, the first transmission shaft 6, the second transmission shaft 7, the third transmission shaft 8, the fourth transmission shaft 9 and the fifth transmission shaft 10 are respectively fixed on the support frame 1 through bearings and are conveniently fixed.

The transmission wheels 11 are respectively arranged on the sides of the tenth gear 22, the eleventh gear 23 and the twelfth gear 24; the transmission wheels 11 are respectively arranged on the sides of the fifth gear 17 and the sixth gear 18; the transmission wheels 11 drive and support the twelve-inch furnace tube 4. One set of device drives two specifications of furnace tubes, is compatible with a variety of specifications, and is capable of improving the efficiency and reducing the cost.

The second gear and the third gear of the driven wheel 5 are concentrically arranged, so that a transmission ratio can be conveniently generated and controlled; the outer diameter of the second gear of the driven wheel 5 is larger than that of the third gear, so that the transmission ratio can be adjusted; the transmission wheels 11 are circular wheels, so that the transmission wheels can conveniently fit and support the twelve-inch furnace tube 4; and the support frame 1 is L-shaped, so that the space can be effectively used.

More than one hook 12 is arranged on the side of the twelve-inch furnace tube 4; the lower parts of the hooks 12 are hook bodies which wrap the twelve-inch furnace tube 4, and the upper parts of the hooks are mounting blocks, so that lifting is facilitated; the driving wheel 2, the first transmission shaft 6, the second transmission shaft 7, the third transmission shaft 8, the fourth transmission shaft 9 and the fifth transmission shaft 10 are parallel to each other, so that the energy transfer efficiency can be improved; the second transmission shaft 7 is located at radial middle parts of the upper parts of the first transmission shaft 6 and the third transmission shaft 8; the first transmission shaft 6, the second transmission shaft 7 and the third transmission shaft 8 are fixed by two support blocks; the fifth transmission shaft 10 is located at radial middle parts of the upper parts of the third transmission shaft 8 and the fourth transmission shaft 9; the third transmission shaft 8, the fourth transmission shaft 9 and the fifth transmission shaft 10 are fixed by two support blocks; and the positions of the transmission wheels 11 are reasonably arranged, so that rotation directions of the transmission wheels 11 are consistent, the supporting is facilitated, and the utilization rate of the space is increased.

The embodiment of the invention also provides a furnace tube washing tank device, comprising the above-described twelve-inch and eight-inch compatible furnace tube washing tank mechanism.

The basic principles, main characteristics and advantages of the invention are shown and described above. Those of ordinary skill in the art shall understand that the invention is not limited by the above-described embodiments, the descriptions in the embodiments and the specification only explain the principles of the invention, the invention also has various changes and improvements on the premise of not deviating from the spirit and the scope of the invention, and the changes and improvements fall within the protection scope of the invention. The protection scope of the invention is defined by the appended claims and equivalents thereof.

We claim:

1. A twelve-inch and eight-inch compatible furnace tube washing tank mechanism, characterized in that the furnace tube washing tank mechanism comprises:
a support frame (1),wherein a driving wheel (2) is arranged at the upper part of the support frame (1); a first gear (13) on the driving wheel (2) is engaged with a second gear (14) of a driven wheel (5); two sides of a third gear (15) of the driven wheel (5) are respectively engaged with a fourth gear (16) of a first transmission shaft (6); the driven wheel (5) drives an eight-inch furnace tube (3);
a fifth gear (17) of the first transmission shaft (6) is engaged with a sixth gear (18) of a second transmission shaft (7); transmission wheels (11) are respectively arranged on the sides of the fifth gear (17) and the sixth gear (18); a seventh gear (19) of the first transmission shaft (6) is engaged with an eighth gear (20) of a third transmission shaft (8); a ninth gear (21) of the third transmission shaft (8) is engaged with a tenth gear (22) of a fourth transmission shaft (9); an eleventh gear (23) of the fourth transmission shaft (9) is engaged with a twelfth gear (24) of a fifth transmission shaft (10); the transmission wheels (11) drive a twelve-inch furnace tube (4); the transmission wheels (11) are respectively arranged on the sides of the tenth gear (22), the eleventh gear (23) and the twelfth gear (24);
the driving wheel (2), the first transmission shaft (6), the second transmission shaft (7), the third transmission shaft (8), the fourth transmission shaft (9) and the fifth transmission shaft (10) are respectively fixed on the support frame (1) through bearings.

2. The twelve-inch and eight-inch compatible furnace tube washing tank mechanism according to claim 1, characterized in that the second gear and the third gear of the driven wheel (5) are concentrically arranged.

3. The twelve-inch and eight-inch compatible furnace tube washing tank mechanism according to claim 1, characterized in that the outer diameter of the second gear of the driven wheel (5) is larger than that of the third gear.

4. The twelve-inch and eight-inch compatible furnace tube washing tank mechanism according to claim 1, characterized in that the transmission wheels (11) are circular wheels.

5. The twelve-inch and eight-inch compatible furnace tube washing tank mechanism according to claim 1, characterized in that the support frame (1) is L-shaped.

6. The twelve-inch and eight-inch compatible furnace tube washing tank mechanism according to claim 1, characterized in that more than one hook (12) are arranged on the side of the twelve-inch furnace tube (4); the lower parts of the hooks (12) are hook bodies which wrap the twelve-inch furnace tube (4), and the upper parts of the hooks (12) are mounting blocks.

7. The twelve-inch and eight-inch compatible furnace tube washing tank mechanism according to claim 1, characterized in that the driving wheel (2), the first transmission shaft (6), the second transmission shaft (7), the third transmission shaft (8), the fourth transmission shaft (9) and the fifth transmission shaft (10) are parallel to each other.

8. The twelve-inch and eight-inch compatible furnace tube washing tank mechanism according to claim 1, characterized in that the second transmission shaft (7) is located at radial middle parts of the upper parts of the first transmission shaft (6) and the third transmission shaft (8); and the first transmission shaft (6), the second transmission shaft (7) and the third transmission shaft (8) are fixed by two support blocks.

9. The twelve-inch and eight-inch compatible furnace tube washing tank mechanism according to claim 1, characterized in that the fifth transmission shaft (10) is located at radial middle parts of the upper parts of the third transmission shaft (8) and the fourth transmission shaft (9); and the third transmission shaft (8), the fourth transmission shaft (9) and the fifth transmission shaft (10) are fixed by two support blocks.

10. A furnace tube washing tank device, characterized in that the furnace tube washing tank device comprises the twelve-inch and eight-inch compatible furnace tube washing tank mechanism according to claim 1.
